(19) United States
(12) Patent Application Publication
(10) Pub. No.: US 2012/0261803 A1
(43) Pub. Date: Oct. 18, 2012

(54) HIGH-K GATE DIELECTRIC MATERIAL AND METHOD FOR PREPARING THE SAME

(76) Inventors: Wenwu Wang, Beijing (CN); Chao Zhao, Kessel-Lo (BE); Kai Han, Beijing (CN); Dapeng Chen, Beijing (CN)

(21) Appl. No.: 13/394,935

(22) PCT Filed: Oct. 17, 2011
(86) PCT No.: PCT/CN11/01727

§ 371 Date: Mar. 8, 2012

(30) Foreign Application Priority Data
Oct. 21, 2010 (CN) 201010520981.4

(51) Int. Cl. H01L 21/31; H01L 29/02

(52) U.S. Cl. 257/632; 438/786; 257/E29.002; 257/E21.24

(57) ABSTRACT

The present invention forms Hf₁₋ₓSiₓO_{y} having a cubic phase or a tetragonal phase by doping a specific amount of SiO₂ component into the high-K gate dielectric material HfO₂ in combination with an optimized thermal processing technique, to thereby acquire a high-K gate dielectric thin film material having a greater bandgap, a higher K value and high thermal stability. Besides, the high-K gate dielectric thin film and a preparation method thereof proposed in the present invention are helpful to solve the problem of crystallization of ultra-thin films.

### CROSS REFERENCE

This application is a National Phase application of, and claims priority to, PCT Application No. PCT/CN2011/001727, filed on Oct. 17, 2011, entitled ‘HIGH-K GATE DIELECTRIC MATERIAL AND METHOD FOR PREPARING THE SAME’, which claimed priority to Chinese Application No. CN 201010520981.4, filed on Oct. 21, 2010. Both the PCT Application and Chinese Application are incorporated herein by reference in their entireties.

### TECHNICAL FIELD

The present invention relates to the field of semiconductor materials and preparation thereof, and particularly to a high-K gate dielectric material and a method for preparing the same.

### BACKGROUND OF THE INVENTION

High-K gate dielectric materials have been widely concerned and used in CMOS (Complementary Metal Oxide Semiconductor) technology, particularly in 45 nm and below technology generation. Introduction of high-K gate dielectric materials may ensure a significant increase in the physical thickness of gate dielectrics with the same equivalent oxide thickness (EOT), to thereby achieve the object of suppressing the gate leakage current. HfO₂ is now considered as one of the high-K gate dielectric materials that are most likely to be applied to CMOS technology. HfO₂ has a relative dielectric constant k ranging from 16 to 25, a bandgap of about 5.8 eV and a conduction band offset of about 1.4 eV, which electrical properties meet the requirements for high-K gate dielectric materials of MOS devices, and is expected to function as a gate dielectric layer of a MOS device to decrease the gate leakage current.

Although HfO₂, as a high-K gate dielectric material, has distinct advantages and application prospects, it also shows deficiencies such as low recrystallization temperature (400-500° C.), thermal instability with Si substrate , and a K value that is expected to be further increased, with continuous reduction in the feature size of a MOS device, particularly when it enters into 32 nm and below technology nodes . Accordingly, how to overcome the above deficiencies becomes the key factor to determine whether HfO₂ can be applied in the next technology node.

Generally, HfO₂ has three different crystalline structures, namely monoclinic phase (with a K value of about 16 and being stable at the room temperature), tetragonal phase (with a K value of about 33 and being stable at about 1800° C.)., and cubic phase (with a K value of about 29 and being stable at about 2700° C.)., as shown in FIG. 1. It has been reported that the polycrystalline structure of an Hf-based high-K gate dielectric material will not result in a too great density of leakage current, and this theory is also proved by Intel Corporation in the industrial production of 45 nm technology generation. Thus, how to design an Hf-based high-K gate dielectric having a fixed crystalline structure through material and process optimization is one of the ways to increase the K value and enhance the thermal stability.

In another aspect, with continuous reduction in the feature size of a MOS device, much higher requirements are raised for the thickness of gate dielectric thin films. As for ultra-thin films (e.g., 1-3 nm), it is rather difficult to form a continuous crystalline structure by current techniques. Therefore, crystallization of ultra-thin films is still one of challenges which are needed to be solved.

### SUMMARY OF THE INVENTION

The present invention aims to solve at least one of the above technical problems, particularly to provide an Hf-based gate dielectric material having a greater bandgap, a higher K value and high thermal stability, to solve the problem of crystallization of ultra-thin films.

To achieve the above object, in one aspect, the present invention proposes a high-K gate dielectric material Hf₁₋ₓSiₓO_{y}, characterized in that: the material Hf₁₋ₓSiₓO_{y} has a cubic phase or a tetragonal phase, the dielectric constant of the material Hf₁₋ₓSiₓO_{y} is in a range of 18-34, and the variable x is in a range of 0.02-0.1.

In another aspect, the present invention proposes a method for preparing a high-K gate dielectric material Hf₁₋ₓSiₓO_{y}, comprising: depositing a material A comprising Hf source and a material B comprising Si source or depositing a material C comprising Hf source and Si source on a semiconductor substrate through a film forming technology; performing annealing at an annealing temperature between 500-800° C. to form an Hf₁₋ₓSiₓO_{y} thin film having a cubic phase or a tetragonal phase, wherein the variable x is in a range of 0.02-0.1.

Preferably, the annealing temperature is in a range of 650-800° C.

Alternatively, the annealing time is in a range of 5-300 s, preferably in a range of 20-120 s.

Alternatively, the annealing atmosphere is N₂ or N₂+O₂, and if the annealing atmosphere is N₂+O₂, the volume content of O₂ is in a range of 0.1%-1%.

Alternately, the film forming technology comprises any one of Physical Vapor Deposition (PVD), Metal Organic Chemical Vapor Deposition (MOCVD), and Atomic Layer Deposition (ALD).

Alternatively, when forming a film by the PVD process, the film may be formed by one of the following methods: co-sputtering the target of the material A and the target of the material B, or sputtering the target of the material C to form an Hf₁₋ₓSiₓO_{y} film having an amorphous phase or a monoclinic phase on the semiconductor substrate; or sputtering the target of the material A and the target of the material B layer by layer alternatively to form one or more deposition cyclic layers on the semiconductor substrate, each of the deposition cyclic layer comprising a layer of the material A and a layer of the material B. Wherein, the material A comprises HfO₂ or Hf, the material B comprises SiO₂ or Si, and the material C comprises a ternary oxide Hf₁₋ₐSiₐO_{b}, wherein the variable a is in a range of 0.02-0.1.

Moreover, when forming a film by a PVD process, the sputtering power of each of the targets or the relative deposition thickness of the materials in each of the deposition cyclic layers is controlled such that the variable x in the formed Hf₁₋ₓSiₓO_{y} thin film is in a range of 0.02-0.1.

Alternatively, when forming a film by the MOCVD process or the ALD process, the film is formed by one of the following methods: introducing the material A and the material B into a reaction chamber simultaneously to form an Hf₁₋ₓSiₓO_{y} thin film having an amorphous phase or a monoclinic phase; or forming one or more deposition cyclic layers by performing deposition layer by layer alternatively, each of the deposition cyclic layer comprising a layer of HfO₂ and a layer of SiO₂, wherein the layer of HfO₂ is formed by reaction of the material A, and wherein the layer of SiO₂ is formed by reaction of the material B. Wherein, the material A comprises one or more of metal organic sources Hf(N(CH₃)₂)₄(TMDEAH), Hf(NC₂H₅CH₃)₄(TEMAH), Hf(N(C₂H₅)₂)₄(TDEAH) and metal inorganic source HfCl₄, or any combination thereof and the material B comprises any one or more of organic compound sources C₈H₂₂N₂Si (SAM24) and HSi[N(CH₃)₂]₃ (3DMAS).

Moreover, when forming a film by an MOCVD process or ALD process, the flow rate of the material A and the material B or the relative deposition thickness of the layer of HfO₂ and the layer of SiO₂ in each of the deposition cyclic layers is controlled such that the variable x in the formed Hf₁₋ₓSiₓO_{y} thin film is in a range of 0.02-0.1.

The present invention forms Hf₁₋ₓSiₓO_{y} having a cubic phase or a tetragonal phase by doping a specific amount of SiO₂ component into the high-K gate dielectric material HfO₂ in combination with an optimized thermal processing technique, to thereby acquire a high-K gate dielectric thin film material having a greater bandgap, a higher K value and high thermal stability. Besides, ultra-thin films with continuous crystalline structure may be easily formed by using the technological process proposed in the present invention, which is helpful to solve the problem of crystallization of ultra-thin films.

Additional aspects and advantages of the present invention will be provided in the descriptions below, some of them will become apparent in the following descriptions or will be known through the practice of the present invention.

### BRIEF DESCRIPTION OF THE DRAWINGS

The above and/or additional aspects and advantages of the present invention will become apparent and more comprehensible in light of the descriptions of the embodiments with reference to the drawings below. The drawings of the invention are illustrative and are not drawn to scale.

FIG. 1 illustrates three crystalline structures of the high-K gate dielectric material HfO₂; and

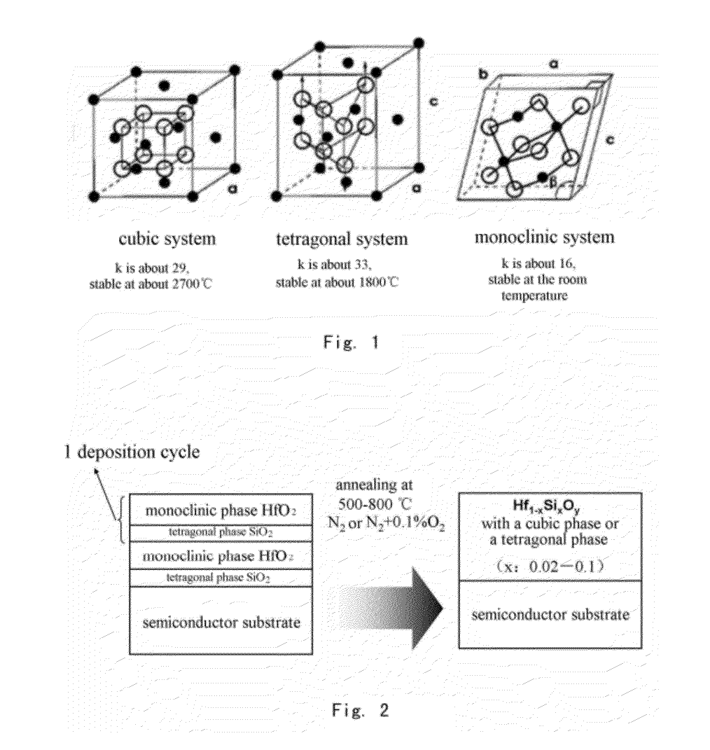

FIGS. 2-4 are schematic diagrams illustrating the method of preparing the gate dielectric material Hf₁₋ₓSiₓO_{y} in the embodiment of the present invention.

### DETAILED DESCRIPTION OF THE EMBODIMENTS

The embodiments of the present invention are described in detail below with reference to the appended drawings, where identical or similar reference signs indicate identical or similar components or components having identical or similar functions throughout the disclosure. The embodiments described below with reference to the drawings are merely illustrative for explaining the present invention only, instead of being construed as limiting the invention.

Many different embodiments or examples are provided in the disclosure herein to implement different structures of the present invention. To simplify the disclosure of the present invention, the components and settings of specific examples are provided below. Of course, they are merely examples, and are not intended to limit the present invention. Furthermore, reference numbers and/or letters may be repeated in different examples of the present invention. Such repetitions are for simplification and clearness, rather than indicating the relations of the discussed embodiments and/or settings. Moreover, the present invention provides examples of various specific processes and materials, but the applicability of other processes and/or application of other materials may be appreciated by those having ordinary skill in the art. Besides, the structure described in the following where a first feature is “above” a second feature may either comprise the embodiment where the first feature and the second feature are in direct contact, or may comprise the embodiment where additional features are between the first feature and the second feature so that the first feature and the second feature may not be in direct contact.

The present invention proposes a high-K gate dielectric material Hf₁₋ₓSiₓO_{y} having a cubic phase or a tetragonal phase, wherein the variable x is in a range of 0.02-0.1, and the dielectric constant is in a range of 18-34. With respect to the common Hf-based high-K gate dielectric materials (e.g., HfO₂), the gate dielectric material proposed by the present invention has a greater band gap, a higher K value and high thermal stability.

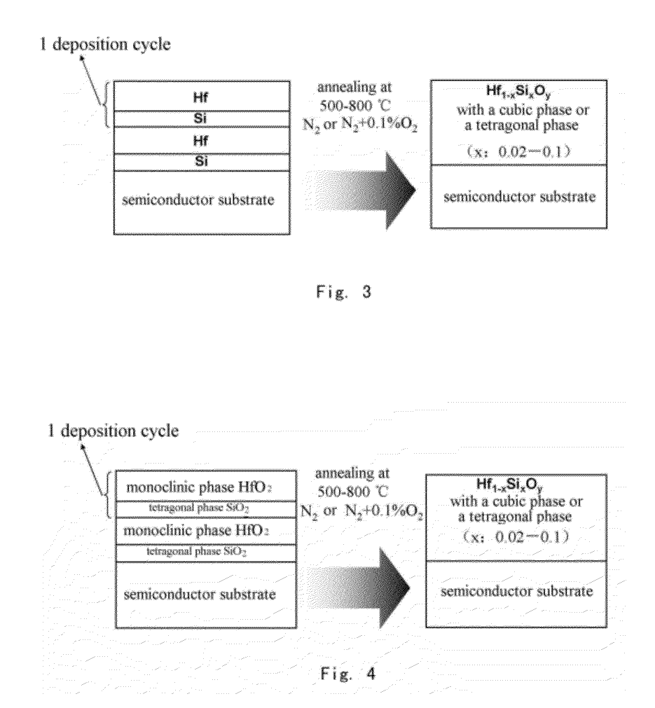

The method for preparing the gate dielectric material Hf₁₋ₓSiₓO_{y} will be described in detail below with reference to FIGS. 2-4. The method comprises the steps of: depositing a material A comprising Hf source and a material B comprising Si source or depositing a material C comprising Hf source and Si source on a semiconductor substrate through a film forming technology; and performing thermal annealing at an annealing temperature between 500-800° C. to form an Hf₁₋ₓSiₓO_{y} film having a cubic phase or a tetragonal phase, where the variable x is in a range of 0.02-0.1. The annealing temperature is preferably in a range of 650-800° C.; the annealing time is in a range of 5-300 s, preferably in a range of 20-120 s; and the annealing atmosphere is N₂ or the combination of N₂+O₂ with the volume content of O₂ in a range of 0.1%-1%.

It should be pointed out that if Hf₁₋ₓSiₓO_{y} does not have sufficient Si, it is rather difficult to convert the HfSiO, in an amorphous or monoclinic phase structure into HfSiO, having a cubic phase or a tetragonal phase by an annealing process. And if the amount of Si in Hf₁₋ₓSiₓO_{y} is too high, phase separation reaction HfSiO_{z}→HfO₂+SiO₂ will occur in HfSiO_{z} in the subsequent thermal annealing process. Separation of SiO₂ will affect the phase structure and the electrical property such as dielectric constant (K value) of the material. Hence, the amount of Si in Hf₁₋ₓSiₓO_{y} shall be controlled at the film forming stage to make the variable x be in a range of 0.02-0.1, which may be achieved by adjusting the component ratio of the material A comprising Hf source to the material B comprising Si source or adjusting the component ratio of Hf source to Si source in the material C.

The film forming technology may be any one of Physical Vapor Deposition (PVD), Pulsed Laser Deposition (PLD), Chemical Vapor Deposition (CVD), Atomic Layer Deposition (ALD), Plasma Enhanced Atomic Layer Deposition (PEALD) or other suitable processes. It is described below a method of preparing the high-K gate dielectric material Hf₁₋ₓSiₓO_{y} by taking the processes of PVD, Metal Organic Chemical Vapor Deposition (MOCVD), and ALD as examples. It should be noted that these embodiments do not intend to limit the present invention, and other appropriate film forming techniques may be incorporated by those having ordinary skill in the art. As long as they are applied to the process conditions and the material components defined by the present invention to form the thin film material Hf₁₋ₓSiₓO_{y} having the same physical property as defined in the present invention, they shall be included within the protection scope of the present invention.

### Embodiment 1

### Film Forming by PVD

First, a film is deposited by a PVD process at a process pressure of about 0.21-1 Pa in the sputtering atmosphere of Ar gas with the flow rate of about 15-50 sccm. The semiconductor substrate may have a temperature ranging from the room temperature to 400° C. Then annealing is performed at a temperature between 500-800° C. in an annealing atmosphere of N₂ or N₂+O₂ in which O₂ occupies 1% (volume ratio) to form an Hf₁₋ₓSiₓO_{y} film having a cubic phase or a tetragonal phase. The film may be formed by the following methods.

Method 1: the targets of the material A comprising Hf source and the material B comprising Si source are sputtered, or the target of the material C comprising Hf source and Si source is sputtered, so as to form an Hf₁₋ₓSiₓO_{y} thin film having an amorphous phase or a monoclinic phase on the semiconductor substrate. Specifically, the materials A and B may be elementary materials such as Hf and Si, or binary oxide such as HfO₂ and SiO₂ , and the material C may be ternary oxide Hf₁₋ₐSiₐO_{b} with predefined component ratio, wherein a is in a range of 0.02-0.1. It should be noted that if the target is an elementary material such as Hf and Si, the sputtering atmosphere may be Ar+O₂. If depositing is performed by co-sputtering, the sputtering power for each of the targets is controlled such that the variable x in the formed Hf₁₋ₓSiₓO_{y} film is in a range of 0.02-0.1.

Method 2: the target of the material A and the target of the material B are sputtered layer by layer alternatively to form one or more deposition cyclic layers on the semiconductor substrate, each of the deposition cyclic layer comprising a layer of the material A and a layer of the material B. Specifically, HfO₂ having a monoclinic phase (material A) and SiO₂ having a tetragonal phase (material B) may be deposited layer by layer alternatively in accordance with certain proportional relation of thickness, and then annealing may be performed according to the above annealing process such that the variable x in the formed Hf₁₋ₓSiₓO_{y} thin film is in a range of 0.02-0.1, as shown in FIG. 2. Alternatively, Hf (material A) and Si (material B) may be deposited layer by layer alternatively in accordance with certain proportional relation of thickness in sputtering atmosphere of pure Ar gas or mixed gas of Ar+O₂, and then annealing may be performed according to the above annealing process such that the variable x in the formed Hf₁₋ₓSiₓO_{y} film is in a range of 0.02-0.1, as shown in FIG. 3.

### Embodiment 2

### Film Forming by MOCVD or ALD

First, a film may be deposited by an MOCVD or ALD process at a temperature in the reaction chamber between 200-600° C., and then annealing is performed at a temperature between 500-800° C. in an annealing atmosphere of N₂ or N₂+O₂ in which O₂ occupies 1% (volume ratio) to form an Hf₁₋ₓSiₓO_{y} film having a cubic phase or a tetragonal phase. The film may be formed by the following methods.

Method 1: the material A comprising Hf source and the material B comprising Si source may be introduced into the reaction chamber simultaneously to form an Hf₁₋ₓSiₓO_{y} thin film having an amorphous phase or a monoclinic phase on the semiconductor substrate. Specifically, the material A comprises any one of metal organic sources Hf(N(CH₃)₂)₄ (TMDEAH), Hf(NC₂H₅CH₃)₄(TEMAH), Hf(N(C₂H₅)₂)₄(TDEAH) and metal inorganic source HfCl₄, or combinations thereof. The material B comprises any one of organic compound sources C₈H₂₂N₂Si(SAM24) and HSi[N(CH₃)₂]₃ (3DMAS), or combinations thereof. And the oxidant may be one or more of H₂O, O₂, NO, N₂O and O₃. It should be noted that the flow rate of the material A and the material B may be controlled during the reaction process such that the variable x in the formed Hf₁₋ₓSiₓO_{y} film is in a range of 0.02-0.1.

Method 2: one or more deposition cyclic layers may be deposited layer by layer alternatively, each of the deposited cyclic layer comprising a layer of HfO₂ having a monoclinic phase and a layer of SiO₂ having a tetragonal phase. The layer of HfO₂ is formed by reaction of the material A, and the layer of SiO₂ is formed by reaction of the material B, as shown in FIG. 4. Selection of the material A and material B as well as the oxide needed by the reaction may be made by referring to the materials listed in Method 1 of this embodiment. It should be noted that during reaction, the relative deposition thickness of the layer of HfO₂ and the layer of SiO₂ in each of the deposited cyclic layers may be controlled such that the variable x in the formed Hf₁₋ₓSiₓO_{y} film is in a range of 0.02-0.1

The present invention forms Hf₁₋ₓSiₓO_{y} having a cubic phase or a tetragonal phase by doping a certain amount of SiO₂ component into the high-K gate dielectric material HfO₂ in connection with an optimized thermal processing technique, to thereby acquire a high-K gate dielectric thin film material having a greater band gap, a higher K value and high thermal stability. Besides, ultra-thin films with continuous crystalline structure may be easily formed by using the technological process proposed in the present invention, which is helpful to solve the problem of crystallization of ultra-thin films.

Although the embodiments of the present invention have been illustrated and described above, those ordinary skilled in the art may make various variations, modifications, substitutions and derivations to these embodiments without departing from the principle and spirit of the present invention. The scope of the present invention is defined by the appended claims as well as the equivalents.

What is claimed is:

1. A high-K gate dielectric material Hf₁₋ₓSiₓO_{y}, characterized in that the material Hf₁₋ₓSiₓO_{y} has a cubic phase or a tetragonal phase, the dielectric constant of the material Hf₁₋ₓSiₓO_{y} is in a range of 18-34, and the variable x is in a range of 0.02-0.1.

2. A method of preparing a high-K gate dielectric material Hf₁₋ₓSiₓO_{y}, comprising:
depositing a material A comprising Hf source and a material B comprising Si source or depositing a material C comprising Hf source and Si source on a semiconductor substrate through a film forming technology;
performing annealing at an annealing temperature between 500-800° C. to form an Hf₁₋ₓSiₓO_{y} thin film having a cubic phase or a tetragonal phase, wherein the variable x is in a range of 0.02-0.1.

3. The method according to claim 2, characterized in that the annealing temperature is in a range of 650-800° C.

4. The method according to claim 2, characterized in that the annealing time is in a range of 5-300 s.

5. The method according to claim 4, characterized in that the annealing time is in a range of 20-120 s.

6. The method according to claim 2, characterized in that the annealing atmosphere is N₂ or N₂+O₂, and if the annealing atmosphere is N₂+O₂, the volume content of O₂ is in a range of 0.1%-1%.

7. The method according to claim 2, characterized in that the film forming technology comprises any one of Physical Vapor Deposition (PVD), Metal Organic Chemical Vapor Deposition (MOCVD), and Atomic Layer Deposition (ALD).

8. The method according to claim 7, characterized in that when forming a film by the PVD process, the film may be formed by one of the following methods:
co-sputtering the target of the material A and the target of the material B, or sputtering the target of the material C to form an Hf₁₋ₓSiₓO_{y} film having an amorphous phase or a monoclinic phase on the semiconductor substrate; or
sputtering the target of the material A and the target of the material B layer by layer alternatively to form one or more deposition cyclic layers on the semiconductor substrate, each of the deposition cyclic layer comprising a layer of the material A and a layer of the material B.

9. The method according to claim 8, characterized in that the material A comprises HfO₂ or Hf, the material B comprises SiO₂ or Si, and the material C comprises a ternary oxide Hf₁₋ₐSiₐO_{b}, wherein the variable a is in a range of 0.02-0.1.

10. The method according to claim 8, characterized in that when forming a film by the PVD process, the sputtering power of each of the targets or the relative deposition thickness of the materials in each of the deposition cyclic layers is controlled such that the variable x in the formed Hf₁₋ₓSiₓO_{y} thin film is in a range of 0.02-0.1.

11. The method according to claim 7, characterized in that when forming a film by the MOCVD process or the ALD process, the film is formed by one of the following methods:
introducing the material A and the material B into a reaction chamber simultaneously to form an Hf₁₋ₓSiₓO_{y} thin film having an amorphous phase or a monoclinic phase; or
forming one or more deposition cyclic layers by performing deposition layer by layer alternatively, each of the deposition cyclic layer comprising a layer of HfO₂ and a layer of SiO₂, wherein the layer of HfO₂ is formed by reaction of the material A, and wherein the layer of SiO₂ is formed by reaction of the material B.

12. The method according to claim 11, characterized in that the material A comprises one or more of metal organic sources Hf(N(CH₃)₂)₄, Hf(NC₂H₅CH₃)₄, Hf(N(C₂H₅)₂)₄ and metal inorganic source HfCl₄ or any combination thereof, and the material B comprises any one or more of organic compound sources C₈H₂₂N₂Si and HSi[N(CH₃)₂]₃.

13. The method according to claim 11, characterized in that when forming a film by the MOCVD process or ALD process, the flow rate of the material A and the material B or the relative deposition thickness of the layer of HfO₂ and the layer of SiO₂ is controlled such that the variable x in the formed Hf₁₋ₓSiₓO_{y} film is in a range of 0.02-0.1.
